(19) United States
(12) Patent Application Publication
(10) Pub. No.: US 2020/0383236 A1
(43) Pub. Date: Dec. 3, 2020

(54) I/O CIRCUIT BOARD FOR IMMERSION-COOLED ELECTRONICS

(71) Applicant: ICEOTOPE LIMITED, ST PETER PORT (GG)

(72) Inventors: Neil Edmunds, South Yorkshire (GB); Kostas Papouis, South Yorkshire (GB)

(21) Appl. No.: 16/463,933

(22) PCT Filed: Nov. 27, 2017
(86) PCT No.: PCT/GB2017/053553

§ 371 Date: May 24, 2019

(30) Foreign Application Priority Data
Nov. 25, 2016 (GB) 1619976.2

(51) Int. Cl. H05K 7/20; H01R 12/70; H01R 13/52

(52) U.S. Cl. CPC H05K 7/20236; H05K 7/20772; H01R 13/5219; H01R 12/7023

(57) ABSTRACT

An electrical interface provides an electrical connection to an electronic device immersed in a fluid. A circuit board has a plurality of surfaces on which electrical connections are provided. A connection port is mounted on a first surface for coupling with a corresponding connector that is electrically connected to the electronic device. A first electrical conductor is provided on the first surface and is connected to the connection port. A second electrical conductor is provided on a surface other than the first surface. The first electrical conductor is coupled to the second electrical conductor by a via comprising a hole in the electronic circuit board. A sealing gasket has an orifice and is mounted on the circuit board, such that: the connection port is accessible from the opposite side of the sealing gasket to the circuit board through the orifice; and the hole is covered by the sealing gasket.

### TECHNICAL FIELD OF THE INVENTION

The invention relates to an electrical interface for providing at least one electrical connection to an electronic device that is immersed in a fluid within a sealed tank, an electronic system comprising such an electrical interface, an connection circuit board for use with an electronic device that is immersed in a fluid within a tank and a method of electrical interfacing.

### BACKGROUND TO THE INVENTION

Electronic components generate heat in operation, which can lead to overheating and consequent damage to the component and other parts of the system. Such electronic components often include motherboards, central processing units (CPUs) and memory modules. It is therefore desirable to cool the component to transfer the heat away from it and maintain the component temperature no higher than the maximum operating temperature that is specified for correct and reliable operation of the component.

International patent publication number WO-2010/130993 and US patent publication number 2010/0290190 (commonly assigned with this invention) describe a cooling device that uses a sealable module for containing one or more heat generating electronic components, together with a liquid coolant in which the electronic components are immersed. Immersion of the electronic components in a fluid (liquid and/or gas) that carries heat away from the electronic components can be thermodynamically-efficient. The coolant may be thermally conductive whilst being electrically non-conductive and may further have advantageous convective properties. Moreover, the coolant can be selected and used so as not to cause damage to the electronic components in normal operation. Nevertheless, the coolant could cause damage elsewhere, for example due to toxicity, corrosion or other reactive, physical or chemical properties.

For these reasons and since the coolant may be costly, it is desirably contained and typically sealed within a container (a tank or case). This is done so that the electronic components are immersed in the coolant, but without the coolant being lost or otherwise exposed outside the tank. A difficulty then presents in making electrical connections between the electronic components within the tank and other electrical components external the tank. Such connections are used for providing power to the immersed electronic components and/or carrying data signals to and from the immersed electronic components. This is especially an issue when the immersed electronic components include a complex circuit board, such as a computer motherboard and a wide variety of power and data input and output connections are typically used. The electrical connections should be achieved in such a way that leakage of the coolant is avoided. Desirably, the technique should be reliable, resilient (especially to regular and/or frequent opening of the tank, for instance for maintenance reasons), flexible (to allow adjustment and/or change of the electronic components) and inexpensive. This issue is not confined to electronic components that are sealed in a container for cooling reasons, but may also be relevant to any scenario in which an electronic component is housed in a sealable or sealed way.

Existing techniques for making electrical connections between components in a sealed tank and components external the tank do not meet all of these objectives. For example, potting of electrical and electronic components is one known approach for making the connections and this is disclosed in International patent publication number WO-2010/130993 and US patent publication number 2010/0290190, for example. However, potting has disadvantages, especially in its ability to prevent leakage of coolant in a wide variety of circumstances. Therefore, finding a better way to make these electrical connections remains a challenge.

### SUMMARY OF THE INVENTION

Against this background, the invention provides an electrical interface in accordance with claim 1, an electronic system in line with claim 18, an connection circuit board as defined by claim 24 and a method of electrical interfacing in accordance with 29. Further features of the invention are detailed in the dependent claims and herein. Features of the method corresponding with those of the system and/or circuit board may additionally be provided.

A (printed) circuit board is used to provide an electrical interface between electronic components in a tank (the sealable or sealed container or case in which the immersed electronic components are housed) and the external environment. The circuit board has a connection port for receiving a connector from the electronic components inside the tank. The connection port is therefore arranged to be within the sealable or sealed volume of the tank, in which the electronic components are housed. The remainder of the circuit board is not intended to be within and/or accessible from the tank internal, sealable or sealed volume. A sealing gasket is used to seal a housing of the tank and the circuit board. An orifice in the sealing gasket allows the connection port to be accessible from within the tank.

In order to carry electrical signals (power and/or data) between the connection port and other parts of the circuit board, one or more vias are used. This may allow the electrical signals to be carried on different surfaces of the circuit board (for example, using tracks, wires or other conductors). In the simplest embodiment, the circuit board may only use two external, opposite surfaces for carrying electrical signals. In other embodiments, the circuit board may be laminated and carry signals on internal (intermediate) surfaces as well as one or more external surfaces. Each via uses a hole in the circuit board to route the signal from one surface to another. Vias allow connections to be made with high bandwidth and therefore help to support high data rate connectivity. The hole may extend entirely between the two surfaces (or through the entire thickness of the circuit board) or only partially between the surfaces (called a ‘blind via’). These holes may allow fluid to leak out from the tank.

Advantageously, the sealing gasket covers each of these holes. This may prevent leakage of fluid (preferably liquid, although optionally gas; typically used as a coolant, the electronic components being immersed in the fluid) from the tank. The remainder of the circuit board and sealing gasket may also seal any opening of the tank housing allowing the connection port to be accessible from within the tank. A corresponding method for providing one or more electrical connections to an electronic device that is immersed in a fluid within a sealed tank is further provided, having steps for providing and/or using the circuit board and sealing gasket arrangement as herein described.

The sealing gasket is therefore mounted on the circuit board, sealing between the circuit board and the tank housing. Such sealing is reliable and resilient to repeated opening and closing of the seal. Moreover, this technique is straightforward to implement and cost-effective. It is also flexible, as will be discussed below.

The circuit board may further have a second connection port on the opposite side of the sealing gasket to the tank, which may allow signals to be coupled from other devices to the electronic components within the tank through the circuit board. The second connection port is typically different in type (physical shape and/or size or configuration) than the other (first) connection port and is preferably of a standard connector type (for instance, Universal Serial Bus, USB). Multiple connections can each be provided using a respective circuit board in accordance with this technique, each of which can have a different type of respective, second connection port. This may allow a range of different connections to be provided to and from the electronic components in the tank. Also, the type of connections can be changed in a straightforward way, without the need to change the electronic components within the tank to which the electrical connections are made.

A connector may be provided to interface with the circuit board's connection port within the tank. Then, a number of different approaches may be used to provide connections from that connector to the electronic components. For instance, wires may be used. Additionally or alternatively, the connector may be mounted on an internal circuit board, which then couples the electrical connections to the electronic components within the tank. The circuit board and sealing gasket may be fixed or attached to each other (and the tank) by fixing connectors, such as screws, bolts, rivets or similar.

In another aspect, another type of (printed) circuit board is provided. This (internal or connection) circuit board may be suitable for immersion in a fluid (in particular, a coolant and/or liquid), especially within a sealable or sealed volume and designed for interfacing with an electronic device that is also immersed in the fluid, in particular within the sealable or sealed volume. The electronic device has a connection port configured to receive an electrical component, for example a battery, and electrically couple to it (by the use of suitable conductors or electrodes on the connection port). The connection circuit board is designed to simulate the connections provided by the electrical component and thereby interface with the connection port on the electronic component. In particular, the circuit board may be sized and/or shaped in the same way as the electrical component it will replace. Additionally or alternatively, it may have electrical conductors on one or more external surfaces of the circuit board, arranged to match conductors or electrodes of the connection port and interface with them to provide at least one electrical connection of the electronic device to and the connection circuit board. Then, the connection circuit board further comprises connections to electrically couple the at least one electrical connection of the electronic device to the electrical component located external the tank.

In certain scenarios, the fluid in which the electronic device is immersed may damage the electrical component or vice versa. By using a circuit board to interface with the electronic device and thereby connect it to the electrical component external the sealable or sealed volume, the electrical component need not be within the volume but no adaptations are needed to the electronic device. The connection circuit board may be used together with any other aspect of the disclosure, particularly the electrical interface described herein. For example, a battery may be mounted on the circuit board external the tank for connection to the electronic components within the tank, such as via the internal circuit board.

### BRIEF DESCRIPTION OF THE DRAWINGS

The invention may be put into practice in a number of ways and preferred embodiments will now be described by way of example only and with reference to the accompanying drawings, in which:

FIG. 1A schematically depicts an exploded isometric view of a first embodiment, comprising a tank, sealing gasket and a plurality of interfacing circuit boards;

FIG. 1B shows a top view of the embodiment of FIG. 1A, in an assembled form;

FIG. 1C shows a bottom view of the embodiment of FIG. 1A, in an assembled form;

FIG. 2A schematically depicts an exploded isometric view of a part of the embodiment of FIG. 1A, showing part of the tank, the sealing gasket and one of the interfacing circuit boards;

FIG. 2B shows an assembled isometric top view of the embodiment of FIG. 2A;

FIG. 2C shows an assembled isometric bottom view of the embodiment of FIG. 2A;

FIG. 2D illustrates the same embodiment and view as FIG. 2B, but with the part of the tank removed for clarity;

FIG. 2E illustrates a top view of the embodiment of FIG. 2A, but with the part of the tank removed for clarity;

FIG. 2F shows a side sectional view of the embodiment of FIG. 2A, in an assembled form;

FIG. 3A depicts an isometric view of a first interfacing circuit board of FIG. 1A;

FIG. 3B shows a top view of the embodiment of FIG. 3A;

FIG. 3C shows a side view of the embodiment of FIG. 3A;

FIG. 4A depicts an isometric view of a second interfacing circuit board of FIG. 1A;

FIG. 4B shows a top view of the embodiment of FIG. 4A;

FIG. 4C shows a side view of the embodiment of FIG. 4A;

FIG. 5A depicts an isometric view of a third interfacing circuit board of FIG. 1A;

FIG. 5B shows a top view of the embodiment of FIG. 5A;

FIG. 5C shows a side view of the embodiment of FIG. 5A;

FIG. 6A depicts an isometric view of a fourth interfacing circuit board of FIG. 1A;

FIG. 6B shows a top view of the embodiment of FIG. 6A;

FIG. 6C shows a side view of the embodiment of FIG. 6A;

FIG. 7A depicts an isometric view of a fifth interfacing circuit board of FIG. 1A;

FIG. 7B shows a top view of the embodiment of FIG. 7A;

FIG. 7C shows a side view of the embodiment of FIG. 7A;

FIG. 8A schematically illustrates an exploded isometric perspective view of a second embodiment, comprising a receiving circuit board, an interfacing circuit board and a connection circuit board;

FIG. 8B depicts the embodiment of FIG. 8A in an assembled form;

FIG. 8C shows a first side view of the embodiment of FIG. 8B;

FIG. 8D shows a top view of the embodiment of FIG. 8B;

FIG. 8E shows a second side view of the embodiment of FIG. 8B

FIG. 8F depicts a first isometric view of the connection circuit board in the embodiment of FIG. 8A;

FIG. 8G depicts a second isometric view of the connection circuit board in the embodiment of FIG. 8A;

FIG. 8H illustrate a first side view of the connection circuit board in the embodiment of FIG. 8A;

FIG. 8I illustrates a second side view of the connection circuit board in the embodiment of FIG. 8A;

FIG. 9A schematically depicts an exploded isometric view of the embodiment of FIG. 1A, with an additional linking circuit board coupled to an interfacing circuit board;

FIG. 9B shows the embodiment of FIG. 9A in an assembled form;

FIG. 10A schematically depicts an isometric view of the linking circuit board coupled to the interfacing circuit board in the embodiment of FIG. 9A;

FIG. 10B shows a top view of the embodiment of FIG. 10A;

FIG. 10C shows front, side and back views of the embodiment of FIG. 10A;

FIG. 10D shows a bottom view of the embodiment of FIG. 10A;

FIG. 11A schematically shows an exploded isometric view of a variant to the embodiment of FIG. 9A, using both common and individual gaskets;

FIG. 11B shows the embodiment of FIG. 11A in an assembled form;

FIG. 11C depicts an isometric view of the common and individual gaskets of FIG. 11A; and

FIG. 11D depicts a top view of the common and individual gaskets of FIG. 11A.

### DETAILED DESCRIPTION OF PREFERRED EMBODIMENTS

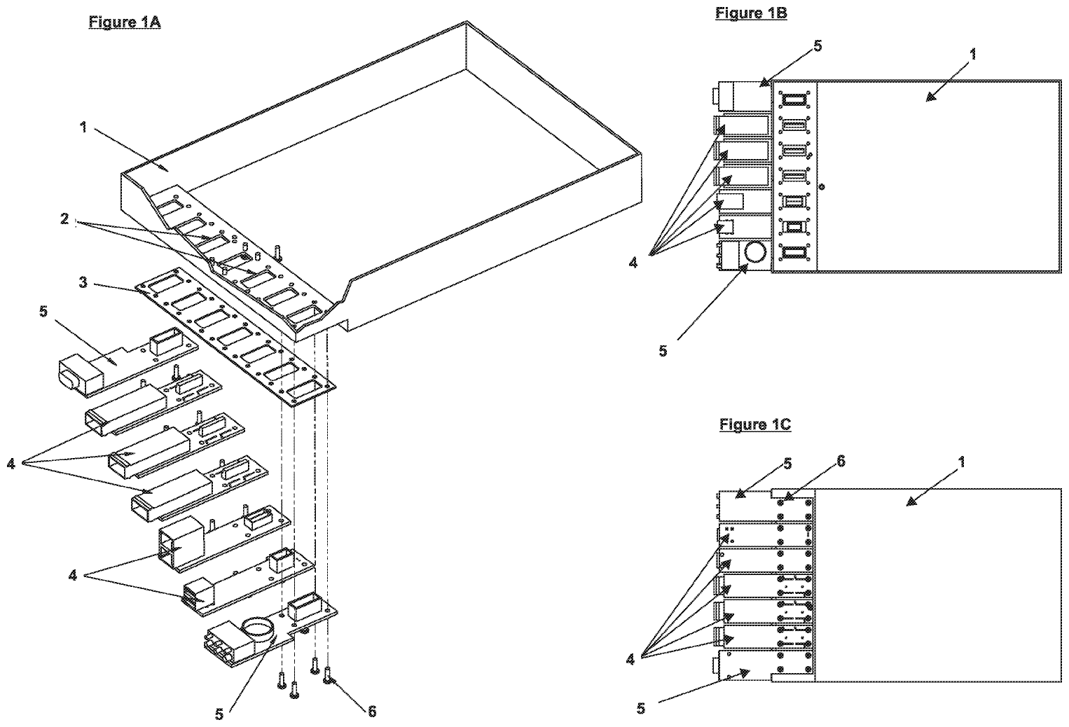

Referring first to FIG. 1A, there is schematically depicted an exploded isometric view of an embodiment. This comprises: a tank 1; a sealing gasket 3; and a plurality of interfacing circuit boards, comprising small footprint circuit boards 4 and large footprint circuit boards 5. Also shown are openings (pass-through holes) 2 in the tank 1, which allow part of the interfacing circuit boards 4, 5 to be accessible from within the tank 1. FIG. 1B shows a top view of the embodiment of FIG. 1A and FIG. 1C shows a bottom view of the embodiment of FIG. 1A, both in an assembled form. The same reference numerals identify the same components in all three drawings.

The tank 1 is designed to be sealed with an electronic device (not shown), comprising electronic components housed therein, together with a fluid coolant (not shown) to make up a module, termed a ‘blade’ in computer server systems. The coolant is typically a dielectric and preferably a liquid. In particular, the coolant may be maintained substantially in liquid form, by preventing the coolant from boiling. This is achieved using a second liquid coolant, external the sealable volume, which carries heat away from the tank. In this approach, there is a first cooling stage, providing by the first liquid coolant within the module and a second cooling stage, provided by the second liquid coolant. Control of the second liquid coolant stage and/or provision of a third liquid coolant stage (receiving heat from the second liquid coolant) may allow thermal control of the first stage accordingly. The interface between the first and second stages is provided as part of the tank, using a heat exchanger (not shown).

In use, the module (comprising the assembled tank and other components, including a further outer housing, which is also not shown) is housed in a rack or cabinet providing connections to corresponding sockets on the module, to allow the second liquid coolant to flow into and out of the module. The connections may be designed for quick release, for instance using suitable valves. The modules are normally designed to be inserted and removed from the rack or cabinet (to allow for maintenance, repair and upgrade of the electronic components, for instance). The electronic device housed in the module may be a computer motherboard. This allows the modules to be used in data processing or computer server centres, where a substantial number of computer processors are co-located and intended for reliable, continuous operation over a long time period. These centres may typically contain many server units, occupying multiple equipment racks and filling one or more rooms. Each server unit contains one or more server boards. A single server board can consume many of hundreds of watts of electrical power, much of which is dissipated as heat. The fluid (liquid) coolant therefore assists in dissipating this heat. More information about possible embodiments of the module can be found in the published patent applications identified above, for example.

When the electronic device and coolant are housed in the tank 1, the tank is sealed partly using further housing, not shown in this drawing. The openings 2 in tank 1 are also sealed and this is achieved as discussed below. Sealing gasket 3 is provided between each of the openings 2 of tank 1 and a respective interfacing circuit board 4, 5. Although a single sealing gasket 3 is shown for all of the openings 2, it will be understood that separate sealing gaskets may alternatively be provided for each opening 2. The sealing gasket 3 has openings corresponding with openings 2 of the tank 1.

Each of the interfacing circuit boards 4, 5 has a connection port that, when assembled, passes through the openings of the sealing gasket 3 and the openings 2 of the tank 1 and is therefore accessible from within the tank 1, even when the tank 1 is sealed. Each interfacing circuit board 4, 5 then has connections to couple the connection port that is accessible from within the tank 1 (referred to as a ‘wet’ side, in view of the preferred use of a liquid within the tank 1) to another connection port that is outside the sealed volume of the tank 1 (referred to as a ‘dry’ side). The sizes and shapes of the openings of the sealing gasket 3 and the openings 2 of the tank 1 are specifically designed to allow the wet side connection port to pass through (in other words, having sufficient clearance), but to be as small as possible so that sealing is made less difficult.

Fixing screws 6 pass though corresponding apertures on the interfacing circuit boards 4, 5, sealing gasket 3 and tank 1 to fix the parts together and hold them in place. This compresses the sealing gasket 3 between each interfacing circuit board 4, 5 and the underside of the housing of tank 1. A seal of each opening 2 is thereby created by the sealing gasket 3 and respective interfacing circuit board 4, 5.

Two different types of interfacing circuit boards 4, 5 are shown. The smaller footprint interfacing circuit board 4 is suitable for use when the dry side connection port is one a majority of standard connector types. Where possible, the smaller footprint interfacing circuit board 4 is used for space efficiency, as it allows more connections to be made. The larger footprint interfacing circuit board 5 can be used instead of the smaller footprint interfacing circuit board 4. This allows large connector types to be provided on the dry side connection port.

The details of the smaller footprint interfacing circuit board 4 and the larger footprint interfacing circuit board 5 will be discussed below. Before this, more information regarding the sealing of the openings 2 will be presented with reference to an example based on the smaller footprint interfacing circuit board 4. However, the skilled person will readily understand the details for sealing openings 2 using the larger footprint interfacing circuit board 5 based on this example.

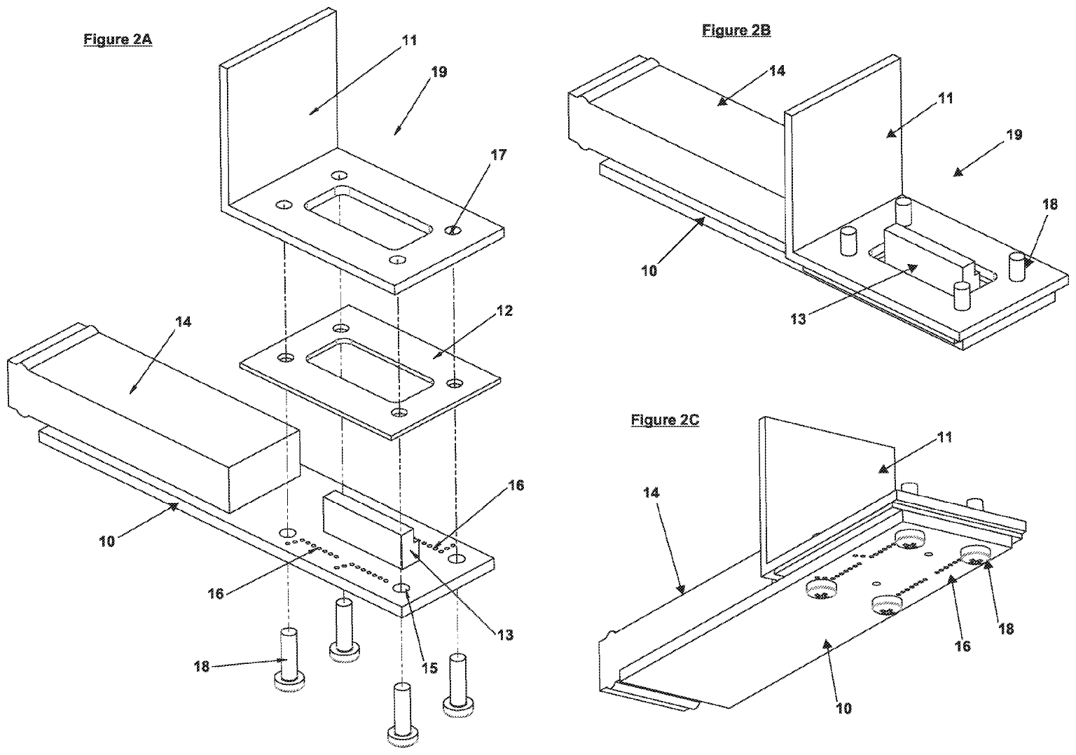

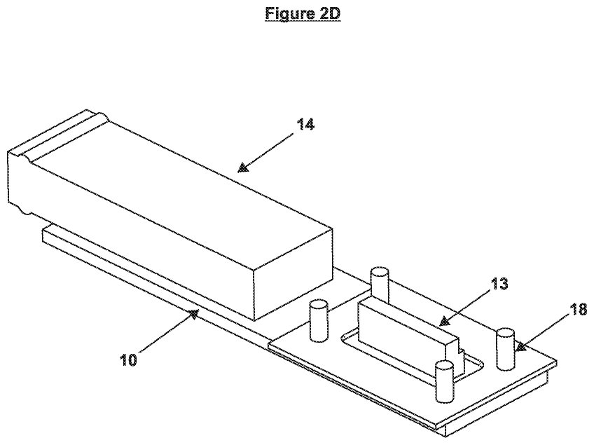

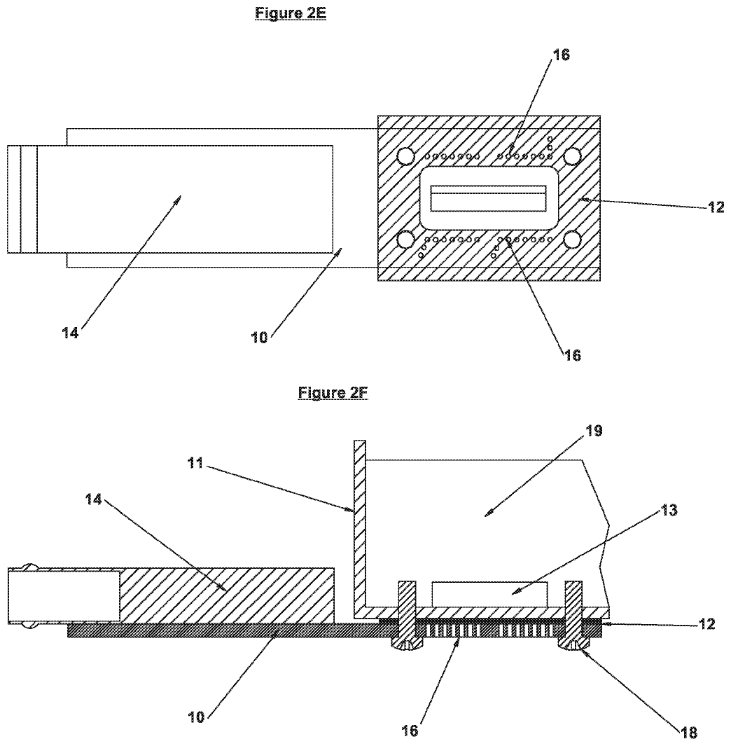

Referring now to FIG. 2A, there is schematically depicted an exploded isometric view of a part of the embodiment of FIG. 1A, showing part of the tank, the sealing gasket and one of the interfacing circuit boards. For clarity, different reference numerals have been used from those employed with respect to previous drawings. Also, there are some slight differences in the illustrations, due to the fact that only a part of the design is shown. With reference to FIGS. 2B and 2C, there are shown assembled isometric views of the embodiment of FIG. 2A, with a top view being shown in FIG. 2B and a bottom view being shown in FIG. 2C.

As illustrated in the previous drawings, there are four main parts to this sealing and interconnection design: the circuit board 10 (normally a printed circuit board, PCB); the tank 11 (shown as a cut away section); the sealing gasket 12; and the fixing screws 18. On the circuit board 10, there is provided a first (wet side) connection port 13 and a second (dry side) connection port 14. As can be seen from the drawing, the first connection port 13 and second connection port 14 are of different types. The first connection port 13 is typically more suited to internal device connections. Generally, the second connection port 14 matches a connection port on the electronic device housed in the tank 11. Since the second connection port 14 is designed to stay on the dry side, it is intended to be readily accessible on a front plane of the module housing (not shown). Using multiple arrangements (as shown in FIGS. 1A, 1B and 1C) may allow multiple connection ports (generally of different types) to all be accessible from the front of the module housing.

Electrical connections between the first connection port 13 and the second connection port 14 use multiple surfaces of the circuit board 10. This uses vias to allow electrical tracks to be routed through different surfaces (or layers) of the circuit board 10. Holes 16 allow the formation of these vias. It should be noted that, for the sake of clarity, the holes 16 shown in these drawings have a larger diameter than would be the case in practice. Normally, the diameter of holes 16 is 0.3 mm. Also, the positioning of the via holes 16 is for illustrative purposes only. The holes 16 typically pass through the entire thickness of the circuit board 10, but this need not be the case and so-called ‘blind’ vias can be employed. Such blind vias are harder to manufacture and may degrade the resilience of the circuit board, in view of it being thin in places.

Advantageously, the holes 16 are positioned under the seal created by the sealing gasket 12. In other words, the sealing gasket 12 covers the holes 16. Covering the holes 16 by sealing gasket 12 in this way creates an improved sealing arrangement. The circuit board 10 may then be used as part of the seal without the risk of leakage through the holes 16.

When the fixing screws 18 pass through PCB through holes 15, sealing gasket 12 and tank fixing holes 17, they can attach and fix the circuit board 10 and sealing gasket 12 to the tank 11 and seal the opening to the tank. Nevertheless, the first connection port 13 passes through the tank housing and is accessible from the wet side 19 of the tank 11. The tank fixing holes 17 are blocked using the fixing screws 18 (and possibly additional components) to completely seal this area of the tank, so that fluid in the tank (for example, coolant) is prevented from leaking. The first connection port 13 can be coupled to the electronic device housed in the tank 11 using a flying lead, for instance. This allows the second connection port 14 to be electrically coupled to the electronic device.

With reference to FIG. 2D, there is illustrated the same embodiment and view as FIG. 2B, but with the part of the tank removed for clarity. Circuit board 10 is shown first connection port 13 and second connection port 14. Sealing gasket 12 is fixed to the circuit board 10 by fixing screws 18. Referring to FIG. 2E, there is illustrated a top view of the embodiment of FIG. 2A, but with the part of the tank removed for clarity. In FIG. 2F there is shown a side sectional view of the embodiment of FIG. 2A, in an assembled form. The same reference numerals as used with respect to FIG. 2A are used in these two drawings, for clarity. As can be seen from FIG. 2F, holes 16 pass through the entire thickness of the circuit board 10. FIG. 2F also shows a portion of the wet side 19 of the tank 11 with more clarity.

In general terms, there may be considered an electrical interface for providing at least one electrical connection (comprising a data connection and/or a power connection) to an electronic device that is immersed in a fluid within a sealed tank. The electrical interface beneficially comprises a circuit board, having a plurality of surfaces on which electrical connections are provided. A connection port is advantageously mounted on a first surface of the circuit board for coupling with a corresponding connector that is electrically connected to the electronic device. One or more first electrical conductors (such as conductive tracks) are provided on the first surface of the plurality of surfaces. The one or more first electrical conductors are connected to the connection port, so as to be connected to the electronic device when the connector is coupled with the connection port. One or more second electrical conductors (for instance, conductive tracks) are each provided on a respective surface of the plurality of surfaces other than the first surface.

Each of the one or more first electrical conductors is coupled to a respective conductor of the one or more second electrical conductors by a respective via. Each via comprises a respective hole in the electronic circuit board. The electrical interface advantageously further comprises a sealing gasket having an orifice. The sealing gasket is mounted on the circuit board, such that the connection port is accessible from the opposite side of the sealing gasket to the circuit board (that is from the area in which the electronic components are located) through the orifice. Beneficially, the sealing gasket is mounted such that the respective hole of each via is covered by the sealing gasket.

There may also be provided an electronic system comprising a tank, having a sealable volume in which an electronic device can be located, the sealable volume allowing the electronic device to be immersed in a fluid. The tank may further comprise an opening to allow one or more electrical connections to be made between the electronic device and components external the sealable volume. The electrical interface as described herein is further provided. In particular, the sealing gasket may be provided between the circuit board and the tank, so as to seal the opening of the tank. Then, the connection port is beneficially provided within the sealable volume through the opening.

The tank is preferably configured such that the electronic device is mounted therein (and especially in the sealable volume of the tank), particularly so that the electronic device is immersed in the fluid. The fluid is typically a liquid. The electronic device generally generates heat in operation. The fluid may be a coolant for removing heat generated by the electronic device. In the preferred embodiment, the electronic device comprises a computer motherboard. Further optional features that may apply to the electrical interface and/or the electronic system may further be described.

The circuit board typically provides more than one connection port. The connection port described above is a first connection port and a second connection port is also mounted on the circuit board in a manner that is non-accessible from the opposite side of the sealing gasket through the orifice (for example, on the opposite side of the sealing gasket to the tank and thereby outside the tank internal volume). The second connection port is coupled to the first connection port by the one or more second electrical conductors. Optionally, the first connection port is of a different type (physical shape and/or size and/or configuration) from the second connection port. In the preferred embodiment, the second connection port is mounted on the first surface of the circuit board (that is the same surface as the first connection port). The second connection port may be of a standard connector type (such as USB). Preferably, the second connection port is of the same type as a connection port on the electronic components to which the first connection is to be electrically connected.

In embodiments, each hole of the at least one via does not fully extend between the first surface and the surface on which the respective conductor of the one or more second electrical conductors is provided or through the entire thickness of the circuit board (a blind via). Alternatively, each hole of the at least one via may extend through the entire thickness of the circuit board.

Although the electrical interface may provide one electrical connection, it will normally be used to provide a plurality of electrical connections. The (first) connection port is typically arranged to provide a plurality of electrical connections to the corresponding connector. Each of the plurality of electrical connections is further provided to a respective one of the one or more first electrical conductors. Optionally, the one or more first electrical conductors comprise a plurality of first electrical conductors and the one or more second electrical conductors comprise a plurality of second electrical conductors. Then, each first electrical conductor may be coupled to a respective second electrical conductor by a respective via.

In some embodiments, only two surfaces of the circuit board are used, typically the top and bottom external surfaces (these being its generally planar external surfaces). The circuit board may be laminated, so as to have at least three surfaces. Then, electrical connections may be provided on more than two surfaces. In this case, the circuit board may further comprise one or more third electrical conductors, each provided on a respective surface of the plurality of surfaces other than the first surface. Each of the one or more third electrical conductors may be coupled to a respective conductor of the one or more second electrical conductors by a respective via. Then, each of these vias may (like the previously discussed vias) comprise a respective hole in the electronic circuit board. In this case, the sealing gasket is advantageously mounted such that the respective hole of each of these vias is covered by the sealing gasket. It may be understood that each of the holes is preferably provided on the opposite side of the sealing gasket to the tank.

The sealing gasket is beneficially attached to the circuit board. One or more fixing connectors may further be provided for attaching the circuit board and the sealing gasket and the fixing connectors may advantageously attach the circuit board and the sealing gasket to the tank. In the preferred embodiment, each of the fixing connectors attaches to the circuit board and the sealing gasket through respective corresponding apertures in the circuit board and the sealing gasket. The fixing connectors may comprise one or more of: screws; bolts; and rivets.

A connector interfaced with the (first) connection port of the electrical interface may further be provided. The connector may provide an electrical connection between the connection port and the electronic device. The electrical connection between the connection port and the electronic device is optionally provided by one or more wires. Additionally or alternatively, the electrical connection between the connection port and the electronic device is provided by an internal (linking) circuit board. The connector may be mounted on the internal circuit board. Then, an internal connection port may further be mounted on the internal circuit board, the internal connection port being configured to mate with a corresponding device connection port that is coupled to (or mounted on) the electronic device. The internal connection port may be of the same type as the second connection port discussed above (but typically of opposite ‘gender’).

In the preferred embodiment, multiple electrical interfaces are used to provide a plurality of electrical connections to respective connector ports on the electronic components within the tank. For example, the tank may comprise a plurality of openings, each opening allowing one or more electrical connections to be made between the electronic device and components external the sealable volume. Then, the electronic system may further comprise a plurality of electrical interfaces, each of the plurality of electrical interfaces being as herein described. The connection port of each electrical interface is beneficially provided within the sealable volume through a respective one of the plurality of openings and each of the plurality of openings is sealed by the sealing gasket of a respective one of the plurality of electrical interfaces. Advantageously, the connection port of a first electrical interface is of a different type than the connection port of a second electrical interface (so that a range of different types of connection port are provided, for instance).

A method of electrical interfacing so to provide at least one electrical connection to an electronic device that is immersed in a fluid within a sealed tank may additionally be considered. The method may comprise steps for providing, mounting or fixing any of the electrical interface and/or electronic system embodiments described herein. For example, the method may comprise: providing a circuit board, having a plurality of surfaces on which electrical connections are provided, a connection port being mounted on a first surface of the circuit board for coupling with a corresponding connector that is electrically connected to the electronic device, one or more first electrical conductors being provided on the first surface of the plurality of surfaces, the one or more first electrical conductors being connected to the connection port so as to be connected to the electronic device when the connector is coupled with the connection port, wherein one or more second electrical conductors are each provided on a respective surface of the plurality of surfaces other than the first surface, each of the one or more first electrical conductors being coupled to a respective conductor of the one or more second electrical conductors by a respective via, each via comprising a respective hole in the electronic circuit board; and mounting a sealing gasket between the circuit board and a housing of the tank, such that the connection port is provided on the same side of the sealing gasket as the tank and such that the respective hole of each via is provided on the opposite side of the sealing gasket to the tank and covered by the sealing gasket. The method optionally further comprises coupling the connection port to the corresponding connector that is electrically connected to the electronic device. Preferably, the method further comprises fixing the circuit board and the sealing gasket to the tank. Other optional and/or advantageous implementation steps corresponding with features described herein may also be considered.

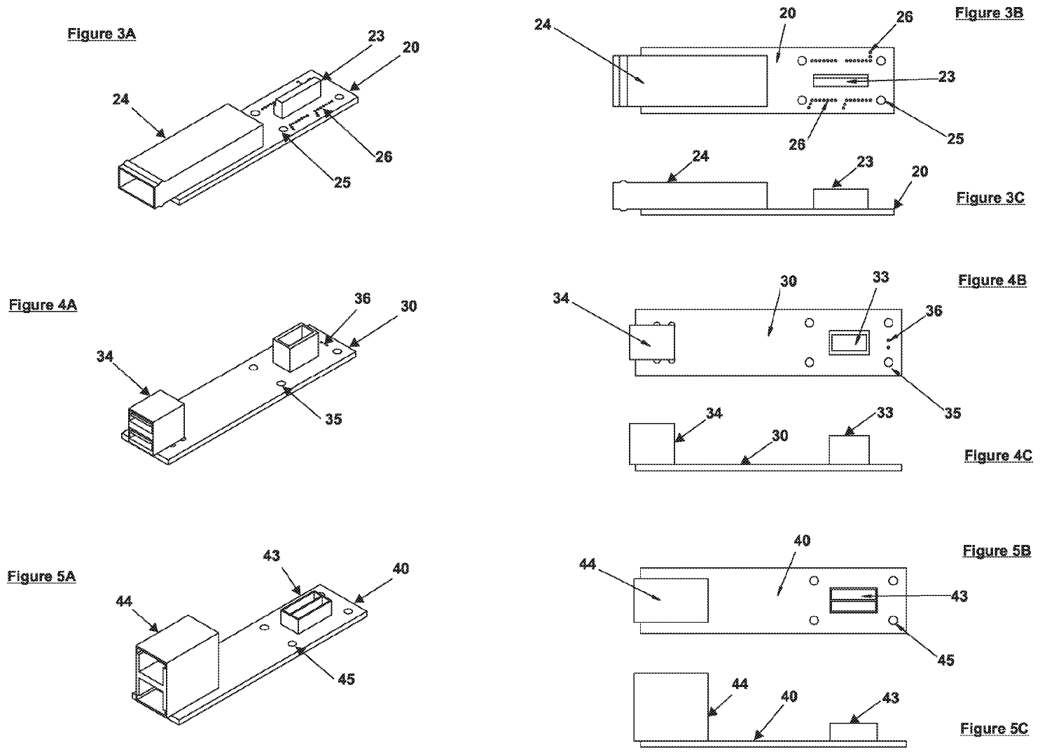

Further embodiments of the interfacing circuit board in different configurations will now be described with reference to additional drawings. Initially, examples with a small footprint will be discussed. Then, with reference to FIG. 3A, there is depicted an isometric view of a first interfacing circuit board of FIG. 1A. In this case, circuit board 20 has a first type of wet side connection port 23. The dry side connection port 24 is of USB Quad Small Form-factor Pluggable (QSFP) type. Fixing holes 25 and via holes 26 are also shown. Referring to FIGS. 3B and 3C, there are shown top and side views of the embodiment of FIG. 3A, respectively.

With reference to FIG. 4A, there is depicted an isometric view of a second interfacing circuit board of FIG. 1A. Here, circuit board 30 has a second type of wet side connection port 33. The dry side connection port 34 is a dual USB socket. Fixing holes 35 and via holes 36 are also shown. Referring to FIGS. 4B and 4C, there are shown top and side views of the embodiment of FIG. 4A, respectively.

With reference to FIG. 5A, there is depicted an isometric view of a third interfacing circuit board of FIG. 1A. Here, circuit board 40 has a third type of wet side connection port 43. The dry side connection port 44 is a dual modular socket, especially RJ45. Fixing holes 45 are also shown. No via holes are shown in this embodiment. Referring to FIGS. 5B and 5C, there are shown top and side views of the embodiment of FIG. 5A, respectively.

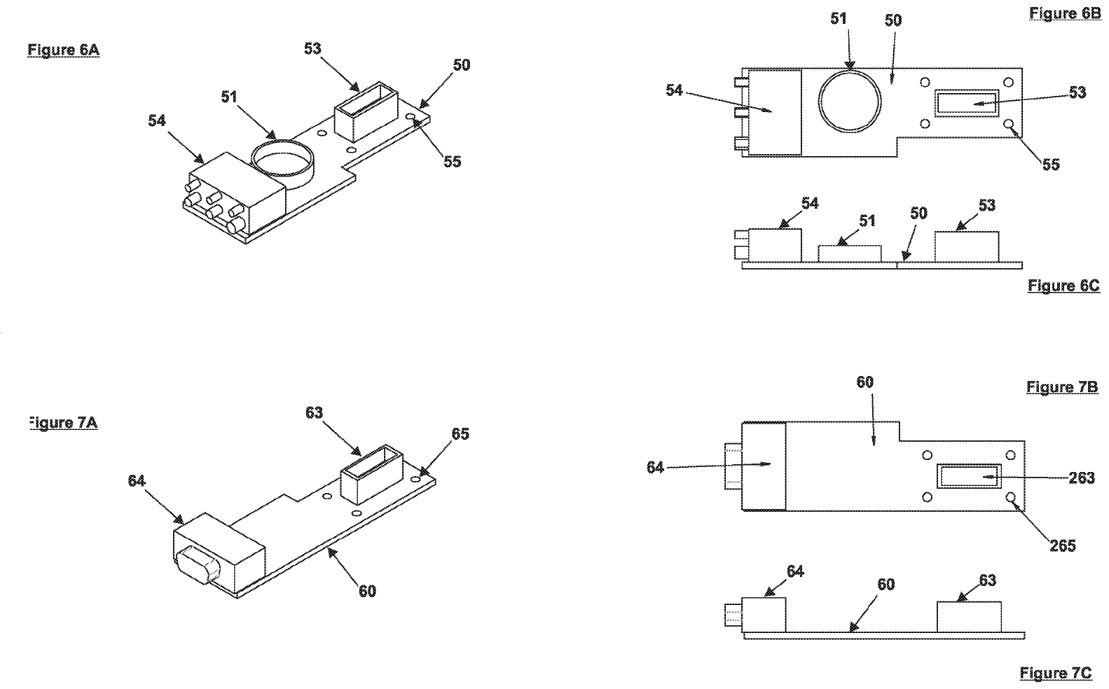

Examples with a large footprint are now presented. With reference to FIG. 6A, there is depicted an isometric view of a fourth interfacing circuit board of FIG. 1A. This is typically used for interfacing with a control and status part of a computer motherboard within the tank. Here, circuit board 50 has a fourth type of wet side connection port 53. It also has an ‘L’-shape, with a wider part nearer the dry side connection port 54. A battery connector 51 (socket or holder) is also provided on the circuit board 50, for receiving a battery. This can further be connected to the computer motherboard in the tank via the wet side connection port 53. Fixing holes 55 are also shown. Referring to FIGS. 6B and 6C, there are shown top and side views of the embodiment of FIG. 6A, respectively.

In one embodiment of the general aspect of the invention discussed above, the electrical connection may comprise a power connection and a battery is further mounted on the circuit board and connected to the one or more second electrical conductors. In this way, a battery connection may be provided to from the circuit board to the electronic components within the tank.

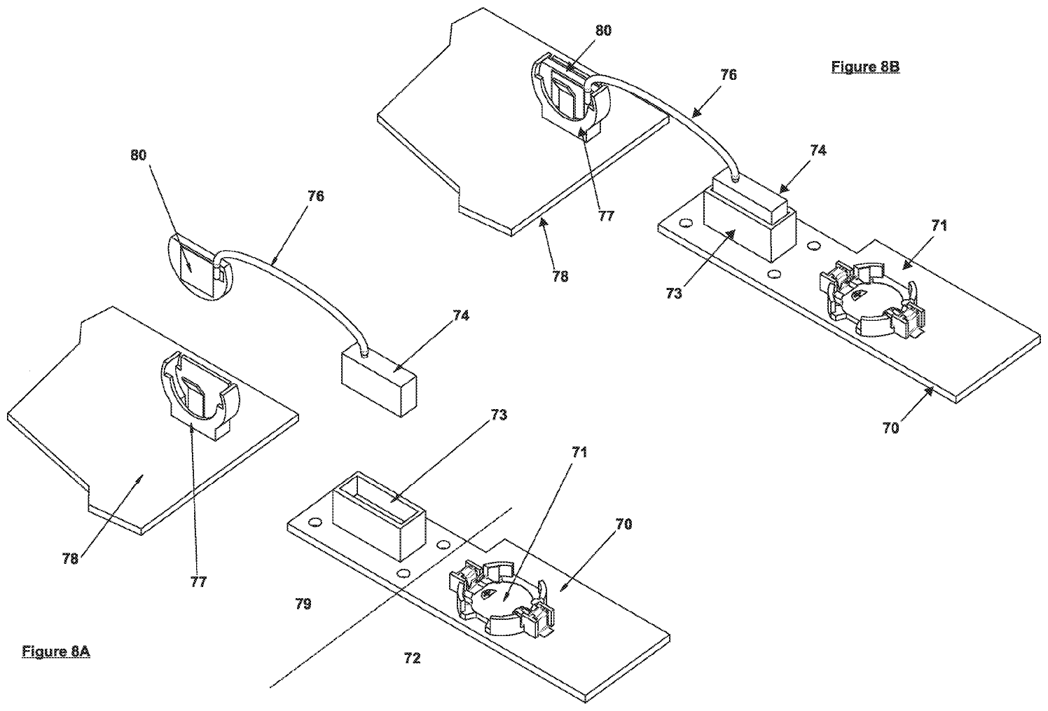

Now referring to FIG. 7A, there is depicted an isometric view of a fifth interfacing circuit board of FIG. 1A. In this embodiment, circuit board 60 has a fifth type of wet side connection port 63 coupled to a VGA-type dry side connection port 64. Like the previous embodiment, the circuit board 60 also has an ‘L’-shape, with a wider part nearer the dry side connection port 64. Fixing holes 65 are additionally shown. Referring to FIGS. 7B and 7C, there are shown top and side views of the embodiment of FIG. 7A, respectively.

Another type of circuit board may be used, especially in connection with the embodiment of FIGS. 6A, 6B and 6C. This is a circuit board shaped in accordance with a battery socket on the electronic components within the tank, in particular to fit a bios battery socket. Such a circuit board may have a similar (or even the same) shape and size as a bios battery that fits the relevant socket. It also has electrical conductors (or electrodes) on the circuit board arranged to match the corresponding electrical conductors or electrodes on the socket. The circuit board is designed for use when immersed in the same fluid as the electronic components (and may therefore be termed an internal circuit board).

Connections are then made from the electrical conductors (or electrodes) on the circuit board to the corresponding wet side connection port on an interfacing circuit board, for instance to wet side connection port 53 of the embodiment of FIGS. 6A, 6B and 6C (which will then couple these connections to the battery connector 51 on the dry side).

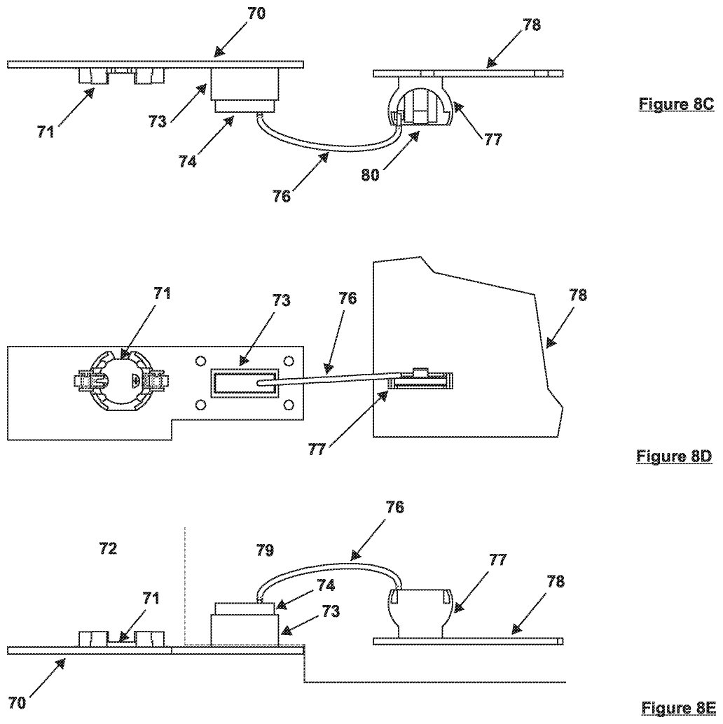

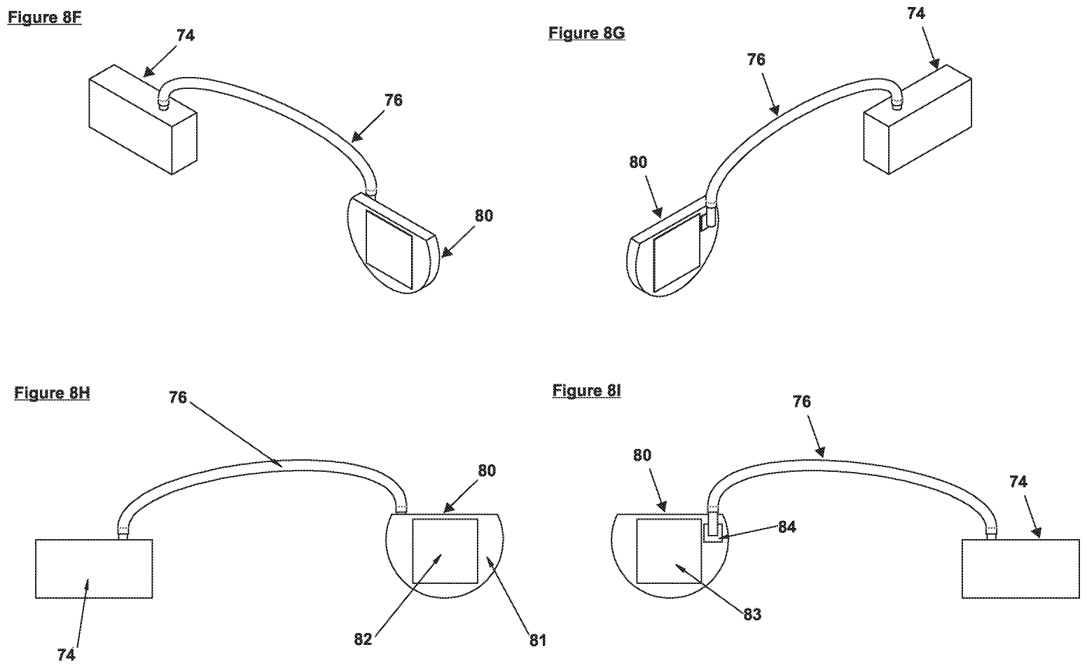

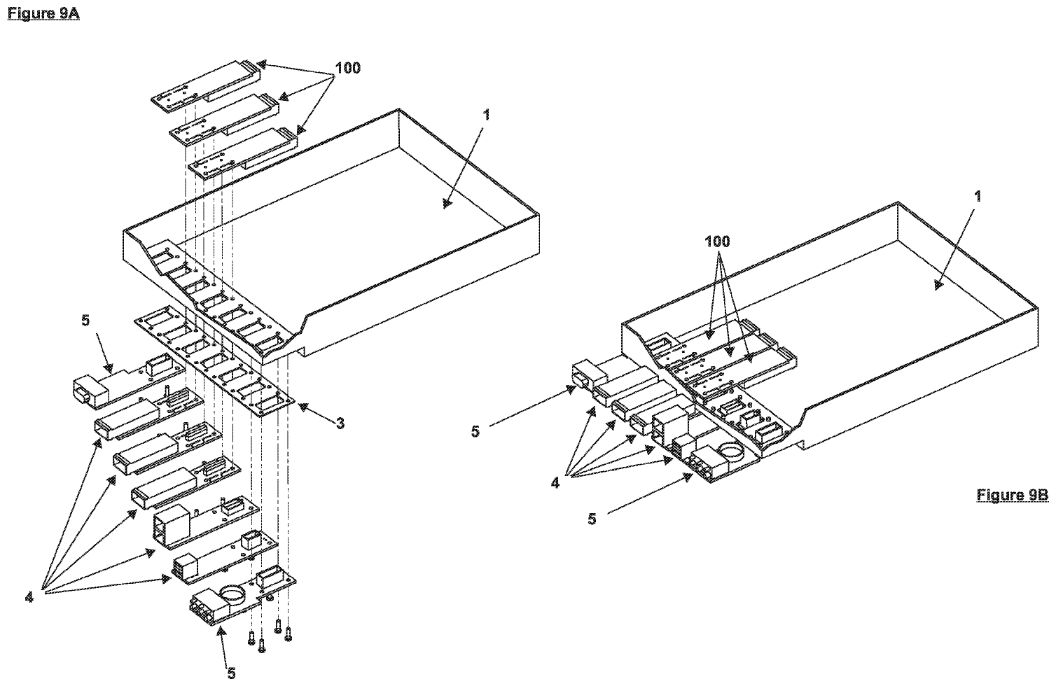

With this in mind, reference is next made to FIG. 8A, in which there is schematically illustrated an exploded isometric perspective view of a second embodiment, comprising a receiving circuit board 78, an interfacing circuit board 70 and a connection circuit board 80. The interfacing circuit board 70 is similar (although not identical) to the fourth interfacing circuit board shown in FIGS. 6A, 6B and 6C. The interfacing circuit board 70 has a battery holder 71 and a wet side connection port 73. The receiving circuit board 78 is part of the electronic components in the tank (for example, a portion of a computer motherboard). As discussed with respect to previous embodiments, the interfacing circuit board is preferably mounted with an appropriate sealing gasket, such that connection port 73 is accessible from inside the tank (that is, on the wet side). For clarity, dry side 72 and wet side 79 have been indicated on this drawing.

A battery holder 77 is mounted on the motherboard. The battery holder 77 is, in this case, designed to receive the same type of battery as the battery holder 71, although it is mounted in a different way from battery holder 71.

The battery holder 71 (on the wet side 79) is electrically connected to the battery holder 77 (on the dry side 72). This is achieved using connection circuit board 80, which is shaped and sized to fit the battery holder 77. Moreover, it is advantageously provided with contacts to match contacts on the battery holder 77. This will be discussed in more detail below. A wire connection 76 couples the contacts on the connection circuit board 80 to a wet side connector 74, designed to mate with the wet side connection port 73 on the interfacing circuit board 70.

Referring next to FIG. 8B, there is depicted the embodiment of FIG. 8A in an assembled form. With reference to FIGS. 8C, 8D and 8E, there are shown a respective first side view, top view and a second side view of the embodiment of FIG. 8B. The same features as shown in FIGS. 8A and 8B are labelled with identical reference numerals. These show the way in which the connection circuit board 80 couples the battery holder 77 on the receiving circuit board 78 to the battery holder 71 on the interfacing circuit board 70. A dashed line in FIG. 8E illustrates the divide between the dry side 72 and the wet side 79.

FIGS. 8F and 8G depict first and second isometric views respectively of the connection circuit board 80 in the embodiment of FIG. 8A, together with the wire connection (lead) 76 and wet side connector 74. With reference to FIGS. 8H and 8I, there are illustrated first and second side views respectively of the connection circuit board 80 in the embodiment of FIG. 8A. Again, the wire connection (lead) 76 and wet side connector 74 are also shown. More details of the connection circuit board 80 are also illustrated. The connection circuit board 80 comprises: a circuit board base 81; a first connection contact 82; a second connection contact 83; and a wire connection contact 84. The first connection contact 82 and the second connection contact 83 are intended to match corresponding contacts or electrodes on the battery holder 77. These are connected to parts of the wire connection contact 84 for connection to the wire connection (lead) 76. The wire connection contact 84 advantageously comprises multiple contacts, each connecting to a respective wire of the wire connection contact 84.

Batteries may not be usable or practical for use in an environment in which they are immersed in certain fluids, especially liquids and/or coolants. The battery may degrade and/or react with the fluid. The use of the circuit board to replace this battery may allow the battery to be placed on the dry side without any adaptation required to the electronic components. Although this technique is described in connection with replacing a battery, it will be understood that it may be used to replace any component that may advantageously be housed on the dry side without the requirement to adapt the electronic components on the wet side.

In a general sense, there may be considered an connection circuit board for use with an electronic device that is immersed in a fluid within a tank. The electronic device has a connection port configured to receive and electrically couple at least one electrical connection of the electronic device to an electrical component. The connection circuit board is configured (in particular shaped and/or dimensioned and/or provided with contacts) to be received at the connection port. It may thereby electrically couple with the at least one electrical connection of the electronic device. The connection circuit board advantageously further comprises connections to electrically couple the at least one electrical connection of the electronic device to the electrical component located external the tank, for example using a wire or lead which may be coupled to a connector. In the preferred embodiment, the electrical component is a battery. It will be understood that this aspect may be combined with any other aspect of the disclosure, in particular the electrical interface as discussed herein.

Although specific embodiments have now been described, the skilled person will appreciate that various modifications and alternations are possible. For instance, different types of connection ports, different shapes of circuit board and different types of fixing connectors or means can be used from those shown. In each of these cases, the skilled person will understand that a range of standard options may exist or design choices may be made according to size and/or user preference.

As has been considered above, the electrical connection between the (wet side) connection port on the interfacing board and the electronic device may be provided by an internal (linking) circuit board. This embodiment will now be discussed in more detail with reference to FIG. 9A, in which there is schematically depicted an exploded isometric view of the embodiment of FIG. 1A, with an additional linking circuit board coupled to an interfacing circuit board. The same features as shown in FIG. 1A are labelled with identical reference numerals. As can be seen in the drawing, additional linking circuit boards 100 are provided, each of which couple to a respective interfacing circuit board 4. The linking circuit boards 100 are designed to be housed with the tank 1 and therefore suitable for immersion in the fluid contained with the tank. Referring to FIG. 9B, there is shown the embodiment of FIG. 9A in an assembled form. This is depicted for the sake of completeness.

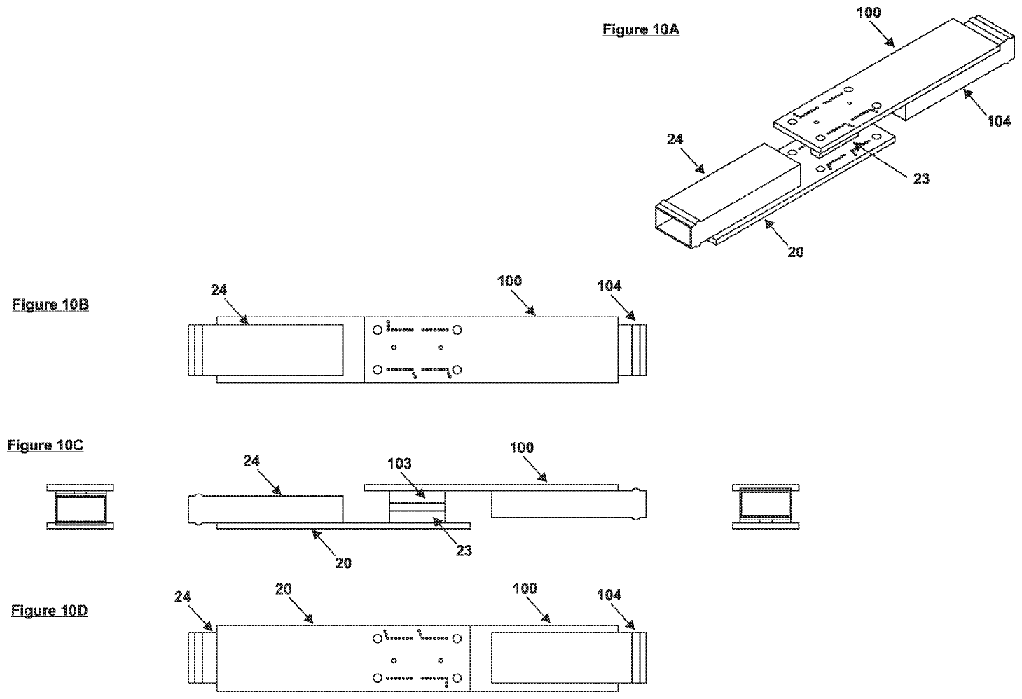

More details regarding the linking circuit board 100 and its coupling with an interfacing circuit board are discussed with reference to FIGS. 10A to 10D. An example of a suitable linking circuit board 100 for interfacing with the first interfacing circuit board 20 of FIGS. 3A to 3C is considered, although it will be recognised that the linking circuit board 100 may be adapted for coupling with other types of interfacing circuit board. Referring to FIG. 10A, there is schematically depicted an isometric view of the linking circuit board 100 coupled to the interfacing circuit board 20. Here, the dry side connection port 24 (of USB QSFP type) on the interfacing circuit board 20 can be seen. A matching internal connection port 104 (of the same USB QSFP type) is provided on the linking circuit board 100. This is intended to couple directly to a corresponding port on the electronic components (not shown) mounted in the tank 1. With reference to FIG. 10B, there is shown a top view of the embodiment of FIG. 10A, FIG. 10C shows front, side and back views of the embodiment of FIG. 10A and FIG. 10D shows a bottom view of the embodiment of FIG. 10A. As can be seen from these drawings, the linking circuit board 100 is further provided with a mating connector 103, for coupling with the wet side connection port 23 of the interfacing circuit board 20. This allows a connection (directly) from the internal connection port 104 to the dry side connection port 24.

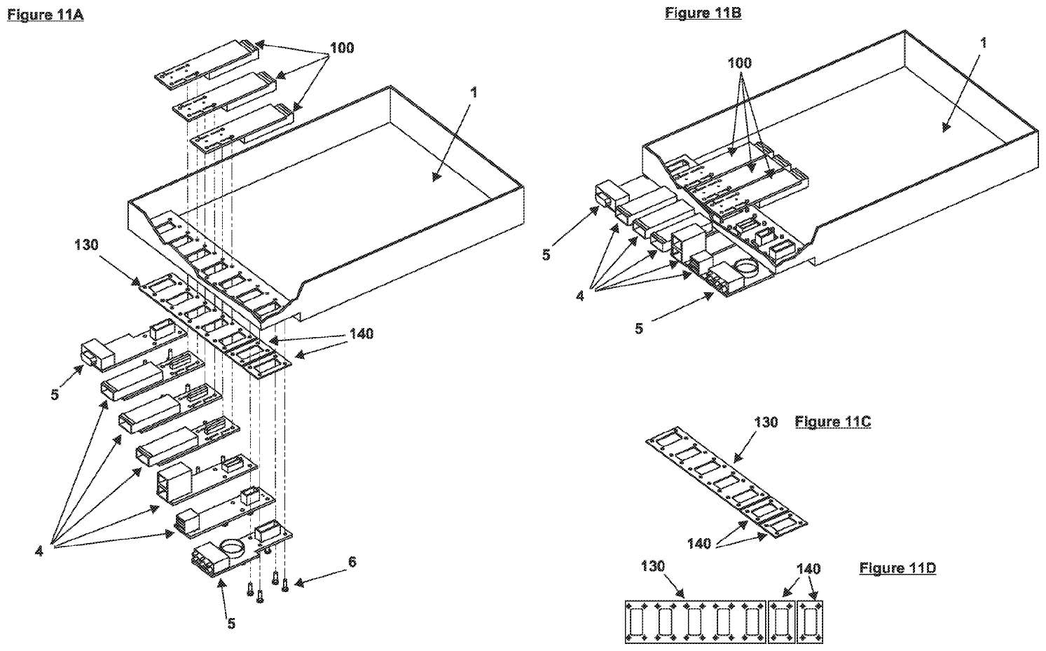

Another variation discussed above relates to the sealing gasket. In consideration of this, reference is made to FIG. 11A, in which there is schematically shown an exploded isometric view of a variant to the embodiment of FIG. 9A, using both a common sealing gasket 130 and individual sealing gaskets 140. The same features as shown in FIG. 9A (and FIG. 1A) are labelled with identical reference numerals. As can be seen, the single common sealing gasket 3 is replaced with two different types of sealing gasket: the common sealing gasket 130 (for sealing a group of adjacent openings) and individual sealing gaskets 140 (for sealing a single opening). The common sealing gasket 130 can be of any size, although it is shown in the illustrated example in the sealing of 5 adjacent openings. Any combination of one or more common sealing gaskets 130 (optionally of different sizes) and one or more individual sealing gaskets 140 can be used in practice.

For the sake of completeness, in FIG. 11B, there is shown the embodiment of FIG. 11A in an assembled form. As can be seen, the common sealing gaskets 130 and individual sealing gaskets 140 may not be visible once assembled. With reference to FIGS. 11C and 11D, there are depicted isometric and top views respectively of the exemplary common sealing gasket 130 and individual sealing gaskets 140.

All of the features disclosed herein may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

1. An electrical interface for providing at least one electrical connection to an electronic device that is immersed in a fluid within a sealed tank, the electrical interface comprising:
a circuit board having a plurality of surfaces on which electrical connections are provided, a connection port being mounted on a first surface of the circuit board for coupling with a corresponding connector that is electrically connected to the electronic device, and one or more first electrical conductors being provided on the first surface of the plurality of surfaces, the one or more first electrical conductors being connected to the connection port so as to be connected to the electronic device when the corresponding connector is coupled with the connection port, wherein one or more second electrical conductors are each provided on a respective surface of the plurality of surfaces other than the first surface, each of the one or more first electrical conductors being coupled to a respective conductor of the one or more second electrical conductors by a respective via, each via comprising a respective hole in the electronic circuit board; and
a sealing gasket having an orifice, the sealing gasket being mounted on the circuit board such that the connection port is accessible from an opposite side of the sealing gasket to the circuit board through the orifice and such that the respective hole of each via is covered by the sealing gasket.

2. The electrical interface of claim 1, wherein the connection port is a first connection port, the circuit board further having a second connection port being mounted on the circuit board in a manner that is non-accessible from the opposite side of the sealing gasket through the orifice, the second connection port being coupled to the first connection port by the one or more second electrical conductors.

3. The electrical interface of claim 2, wherein the second connection port is mounted on the first surface of the circuit board.

4. The electrical interface of claim 2, wherein the first connection port is of a different type from the second connection port.

5. The electrical interface of claim 1, wherein the connection port is arranged to provide a plurality of electrical connections to the corresponding connector, each of the plurality of electrical connections being further provided to a respective one of the one or more first electrical conductors.

6. The electrical interface of claim 1, wherein the one or more first electrical conductors comprise a plurality of first electrical conductors and the one or more second electrical conductors comprise a plurality of second electrical conductors, each first electrical conductor being coupled to a respective second electrical conductor by a respective via.

7. The electrical interface of claim 1, wherein the at least one electrical connection comprises a data connection and/or a power connection.

8. The electrical interface of claim 7, wherein the at least one electrical connection comprises the power connection, the circuit board further having a battery further being mounted on the circuit board and connected to the one or more second electrical conductors.

9. The electrical interface of claim 1, wherein the circuit board is laminated so as to have at least three surfaces, of the plurality of surfaces, on which the electrical connections are provided.

10. The electrical interface of claim 9, wherein the circuit board further comprises one or more third electrical conductors each provided on the respective surface of the plurality of surfaces other than the first surface, each of the one or more third electrical conductors being coupled to the respective conductor of the one or more second electrical conductors by the respective via, the each via comprising the respective hole in the electronic circuit board, the sealing gasket being mounted such that the respective hole of the each via is covered by the sealing gasket.

11. The electrical interface of claim 1, wherein the respective hole of at least one via does not fully extend between the first surface and the respective surface on which the respective conductor of the one or more second electrical conductors is provided.

12. The electrical interface of claim 1, further comprising fixing connectors for attaching the circuit board and the sealing gasket to the sealed tank.

13. The electrical interface of claim 12, wherein each of the fixing connectors attaches to the circuit board and the sealing gasket through respective corresponding apertures in the circuit board and the sealing gasket.

14. The electrical interface of claim 13, wherein the fixing connectors comprise one or more of: screws; bolts; or rivets.

15. The electrical interface of claim 1, wherein the sealed tank is configured such that the electronic device is mounted therein, so that the electronic device is immersed in the fluid.

16. The electrical interface of claim 1, wherein the fluid is a liquid.

17. The electrical interface of claim 1, wherein the electronic device comprises a computer motherboard.

18. An electronic system, comprising:
a tank, having a sealable volume in which an electronic device is capable of being located, the sealable volume allowing the electronic device to be immersed in a fluid, an opening being provided in the tank to allow one or more electrical connections to be made between the electronic device and components external to the sealable volume; and
an electrical interface, wherein a sealing gasket is provided between a circuit board and the tank so as to seal an opening of the tank, a connection port being provided within the sealable volume through the opening.

19. The electronic system of claim 18, further comprising the electronic device, mounted in the sealable volume.

20. The electronic system of claim 18, wherein the electronic device generates heat in operation, the fluid being a coolant for removing the heat generated by the electronic device.

21. The electronic system of claim 18, further comprising a connector interfaced with the connection port and providing an electrical connection between the connection port and the electronic device.

22. The electronic system of claim 21, wherein the electrical connection between the connection port and the electronic device is provided by one or more wires.

23. The electronic system of claim 21, wherein the electrical connection between the connection port and the electronic device is provided by an internal circuit board, a connector being mounted on the internal circuit board, an internal connection port further being mounted on the internal circuit board, the internal connection port being configured to mate with a corresponding device connection port that is coupled to the electronic device.

24. The electronic system of claim 18, wherein the opening comprises a plurality of openings, each opening allowing the one or more electrical connections to be made between the electronic device and the components external to the sealable volume; and
wherein the electrical interface comprises a plurality of electrical interfaces, each of the plurality of electrical interfaces being associated with a corresponding connection port, wherein the corresponding connection port of each electrical interface is provided within the sealable volume through a respective one of the plurality of openings and each of the plurality of openings is sealed by the sealing gasket of a respective one of the plurality of electrical interfaces.

25. The electronic system of claim 24, wherein a connection port of a first electrical interface, of the plurality of electrical interfaces, is of a different type from a connection port of a second electrical interface of the plurality of electrical interfaces.

26. An connection circuit board for use with an electronic device that is configured to be immersed in a fluid within a tank, the electronic device having a connection port configured to receive and electrically couple at least one electrical connection of the electronic device to an electrical component and the connection circuit board being configured to be received at the connection port and thereby electrically couple with the at least one electrical connection of the electronic device, the connection circuit board further comprising connections to electrically couple the at least one electrical connection of the electronic device to the electrical component located external to the tank.

27. The connection circuit board of claim 26, wherein the electrical component is a battery.

28. The electronic system of claim 18, further comprising a connection circuit board, wherein the connection circuit board is coupled to the electrical interface through the connection port of the electrical interface.

29. A method of electrical interfacing so to provide at least one electrical connection to an electronic device that is immersed in a fluid within a sealed tank, the method comprising:
providing a circuit board having a plurality of surfaces on which electrical connections are provided, a connection port being mounted on a first surface of the circuit board for coupling with a corresponding connector that is electrically connected to the electronic device, and one or more first electrical conductors being provided on the first surface of the plurality of surfaces, the one or more first electrical conductors being connected to the connection port so as to be connected to the electronic device when the corresponding connector is coupled with the connection port, wherein one or more second electrical conductors are each provided on a respective surface of the plurality of surfaces other than the first surface, each of the one or more first electrical conductors being coupled to a respective conductor of the one or more second electrical conductors by a respective via, each via comprising a respective hole in the electronic circuit board; and
mounting a sealing gasket between the circuit board and a housing of the sealed tank such that the connection port is provided on a same side of the sealing gasket as the sealed tank and such that the respective hole of each via is provided on an opposite side of the sealing gasket to the sealed tank and covered by the sealing gasket.

30. The method of claim 29, further comprising:
coupling the connection port to the corresponding connector that is electrically connected to the electronic device.

31. The method of claim 29, further comprising:
fixing the circuit board and the sealing gasket to the sealed tank.
